(19) United States
(12) Patent Application Publication
(10) Pub. No.: US 2007/0148944 A1
(43) Pub. Date: Jun. 28, 2007

(54) Interconnection of Semiconductor Device and Method for Manufacturing the Same

(76) Inventor: Han Choon Lee, Seoul (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/613,512

(22) Filed: Dec. 20, 2006

(30) Foreign Application Priority Data
Dec. 28, 2005 (KR) 10-2005-0131200

(51) Int. Cl. H01L 21/44

(52) U.S. Cl. 438/597

(57) ABSTRACT

A method for manufacturing an interconnection of a semiconductor device is provided. The method can include the steps of: forming an interlayer dielectric layer on a semiconductor substrate; forming a damascene pattern on the interlayer dielectric layer; depositing a seed layer on the interlayer dielectric layer; depositing a metal layer on the seed layer; depositing a copper layer on the metal layer for forming a copper interconnection; and performing a heat treatment process such that the metal layer reacts with the copper layer to produce an alloy layer including copper.

### RELATED APPLICATION

This application claims the benefit under 35 U.S.C. §119(e), of Korean Patent Application Number 10-2005-0131200 filed Dec. 28, 2005, which is incorporated herein by reference in its entirety.

### FIELD OF THE INVENTION

The present invention relates to an interconnection of a semiconductor device and a method for manufacturing the same.

### BACKGROUND OF THE INVENTION

In manufacturing a semiconductor device, a metal interconnection is used to electrically connect devices and interconnections to each other. Aluminum (Al), aluminum alloys and tungsten (W) have been extensively used as materials for the metal interconnection.

However, as the semiconductor device has become highly integrated, such metals having a low melting point and a high specific resistance are not suitable for the highly integrated semiconductor device.

The materials having superior conductivity such as copper (Cu), gold (Au), silver (Ag), cobalt (Co), chrome (Cr) or nickel (Ni) have been used as a substitute material for the conventional metal interconnection material. Among the above materials, copper and copper alloys having low specific resistance, superior reliability for electro migration and stress migration and cost competitiveness have been extensively used.

A metal interconnection using copper is generally formed by a damascene process. According to the damascene process, a trench is formed in an insulting layer by photo and etching processes, and is filled with a conductive material such as tungsten (W), aluminum (Al) or copper (Cu), and a part of the conductive material except for the conductive material necessary for the interconnection is removed by etch back or CMP (Chemical Mechanical Polishing) so that the interconnection having a shape of the trench is formed.

That is, in the damascene process, after a conductive layer having a thickness sufficient for completely filling the trench is deposited, the thick conductive layer formed in an area except for the trench area is polished by a CMP process. In this case, due to over-polish and the increase of CMP speed, scratch or a dishing phenomenon causing a surface of the conductive layer to be recessed may be generated.

The copper interconnection having dishing phenomenon or scratch may not be easily connected to a via of an upper copper metal, so that electricity is interrupted or resistance is increased, thereby exerting bad influence upon the reliability of the device.

Further, in the case of excessive scratch, the copper interconnection is not connected with the upper metal layer, thereby causing degradation of the device yielding rate.

### BRIEF SUMMARY

An object of the present invention is to provide an interconnection of a semiconductor device and a method for manufacturing the same, capable of improving reliability of a semiconductor device.

Another object of the present invention is to provide a semiconductor device and a method for manufacturing the same, capable of preventing or minimizing scratch formation when planarizing a copper interconnection.

A method for manufacturing an interconnection of a semiconductor device according to an embodiment of the present invention comprises: forming an interlayer dielectric layer on a semiconductor substrate; forming a damascene pattern on the interlayer dielectric layer; depositing a seed layer on the interlayer dielectric layer; depositing a metal layer on the seed layer; forming a copper interconnection on the metal layer; and performing a heat treatment process, which subjects the metal layer to a chemical reaction, thereby forming the metal layer into an alloy layer including copper.

In another embodiment, a method for manufacturing a damascene interconnection of a semiconductor device by filling a damascene pattern with copper comprises: depositing a predetermined metal by PVD or CVD to form a metal layer on the damascene pattern; forming a copper interconnection on the metal layer, and performing a predetermined heat treatment process on the copper interconnection, which subjects the metal layer to a chemical reaction, thereby forming the metal layer into an alloy layer including copper.

The interconnection of the semiconductor device according to an embodiment the present invention comprises a semiconductor substrate; an interlayer dielectric layer having a damascene pattern formed on the semiconductor substrate; an alloy layer formed in the damascene pattern and including copper through a predetermined heat treatment process; and a copper interconnection formed on the alloy layer.

### BRIEF DESCRIPTION OF THE DRAWINGS

FIGS. 1 to 6 are views for illustrating a method for forming a damascene interconnection of a semiconductor device according to an embodiment of the present invention.

FIGS. 7 to 13 are views for illustrating a method for forming a damascene interconnection of a semiconductor device according to another embodiment of the present invention.

### DETAILED DESCRIPTION OF THE INVENTION

Hereinafter, preferred embodiments of the present invention will be described in detail with reference to the accompanying drawings. However, the present invention is not limited to these embodiments, but various modifications and variations can be made within the scope of the present invention. Such modifications and variations are also within the scope of the appended claims.

In the figures, thickness of layers and areas will be enlarged for the purpose of clarity, and the same reference numerals will be used to refer to the same or like elements throughout the description. When layers, films, areas and plates are expressed as they are formed on other elements, it may not exclude another elements interposed therebetween. In contrast, if elements are expressed as they are directly formed on other elements, it may exclude other elements interposed therebetween.

FIGS. 1 to 6 are views for illustrating a method for forming a damascene interconnection of a semiconductor device according to a first embodiment of the present invention.

Referring to FIG. 1, a first interlayer dielectric layer 2 and a second interlayer dielectric layer 3 can be sequentially stacked on a semiconductor substrate 1 including a thin film having a device electrode or a conductive layer.

Then, a damascene pattern 10 can be formed on the first and second interlayer dielectric layers 2 and 3 by photo and etching processes.

In a further embodiment, a first etch barrier layer can be formed between the first interlayer dielectric layer 2 and the semiconductor substrate 1. That is, the first etch barrier layer can be formed on the semiconductor substrate 1 to serve as an etch stopper when etching the first interlayer dielectric layer 2.

In addition, a second etch barrier layer can be formed between the first interlayer dielectric layer 2 and the second interlayer dielectric layer 3. That is, the second etch barrier layer can be formed on the first interlayer dielectric layer 2 to serve as an etch stopper when etching the second interlayer dielectric layer 3. In an embodiment, the second etch barrier layer can be a nitride layer (SiN) formed by PECVD (Plasma Enhanced CVD).

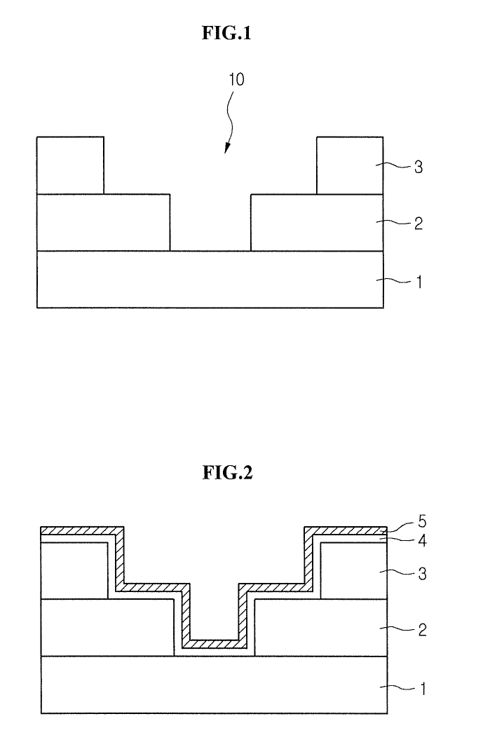

Referring to FIG. 2, after forming the damascene pattern 10, a diffusion barrier 4 and a seed layer 5 can be sequentially deposited on a part of the first and second interlayer dielectric layers 2 and 3 exposed by the damascene pattern.

In detail, the diffusion barrier 4 prevents copper of a copper interconnection filled in the damascene pattern 10 from diffusing into the first and second interlayer dielectric layers 2 and 3.

The diffusion barrier 4 can be formed by means of PVD (Physical Vapor Deposition) or CVD (Chemical Vapor Deposition) using Ti, TiN or a stack structure thereof.

Further, the seed layer 5 can be formed on the diffusion barrier 4. The seed layer 5 smoothly provides the copper interconnection 7, which will be filled in the damascene pattern 10, with electrons so as to help the growth of the copper interconnection 7.

In addition, in one embodiment the seed layer 5 can be formed by CVD (Chemical Vapor Deposition) using copper.

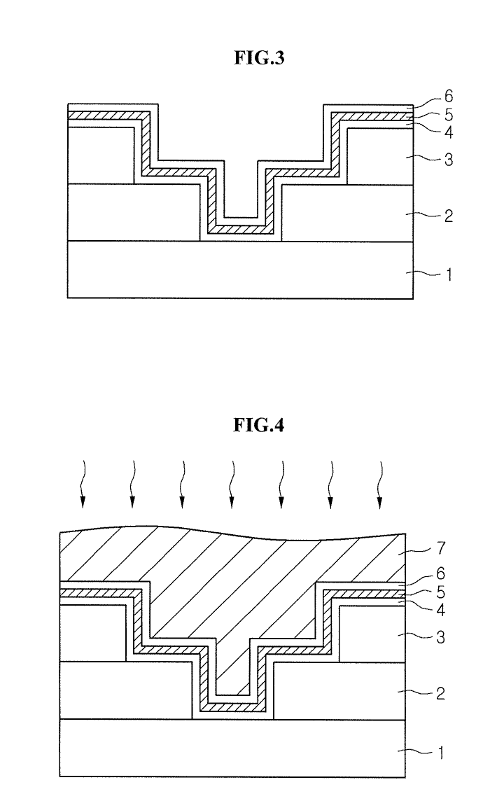

Referring to FIG. 3, a metal layer 6 can be deposited on the seed layer 5 with a predetermined thickness.

The metal layer 6 can be a metal selected from the group consisting of aluminum (Al), manganese (Mn), magnesium (Mg), silver (Ag) and gold (Au). In another embodiment, the metal layer 6 can include silicon. In a specific embodiment, the metal layer 6 may include aluminum that easily reacts with the copper that will be filled in the damascene pattern 10.

The metal layer 6 can be deposited with a thickness of 300 Å or less by PVD (Physical Vapor Deposition), CVD (Chemical Vapor Deposition) or ALD (Atomic Layer Deposition).

The thickness of the metal layer 6 is determined by taking the reaction between the metal layer 6 and copper into consideration in a heat treatment process which is described below.

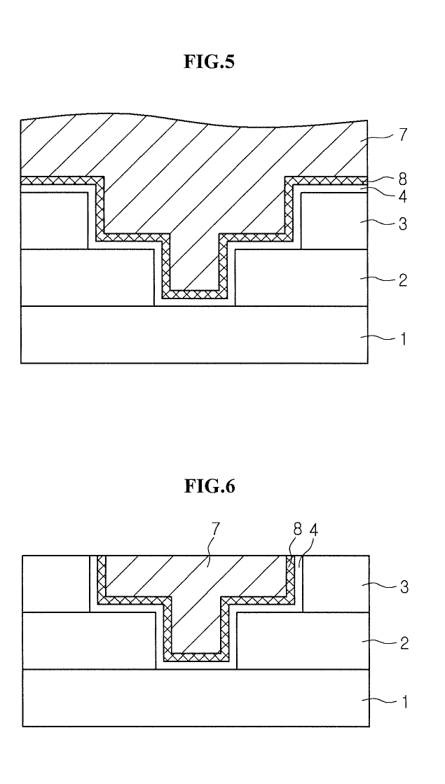

Then, referring to FIG. 4, copper 7 can be formed on the metal layer 6 for interconnect between layers by ECP (Electro Copper Plating) or CVD, so as to form the copper interconnection 7 (shown in FIG. 6).

Then, an annealing process can be performed within a temperature range of 300° C. ± 100° C.

The metal layer 6 and the copper may interact with each other when the annealing process is performed.

Referring to FIG. 5, The heat treatment process causes the metal layer 6 to interact with the copper around the metal layer 6 so as to form an alloy layer 8 in the form of CuₓY_{z}.

In detail, the alloy layer 8 prevents scratch during the CMP (Chemical Mechanical Polishing) process. For example, when the metal layer 6 includes aluminum, the alloy layer 8 is CuAl.

Accordingly, the hardness of the interconnection increases because of the formation of the alloy layer 8, such as CuAl, so that the efficiency of the CMP process is improved.

When depositing the copper prior to the annealing process, the seed layer 5 can be diffused into the copper interconnection 7 while promoting the growth of copper filled in the damascene pattern 10. Accordingly, the alloy layer 8 is formed on the diffusion barrier 4. Then, referring to FIG. 6, a planarization process is performed on the surface of the copper interconnection 7 through the CMP process.

In particular, because the alloy layer 8 is formed under the copper interconnection 7, the hardness of the copper interconnection 7 increases, so that it is possible to prevent scratch from occurring during the CMP process.

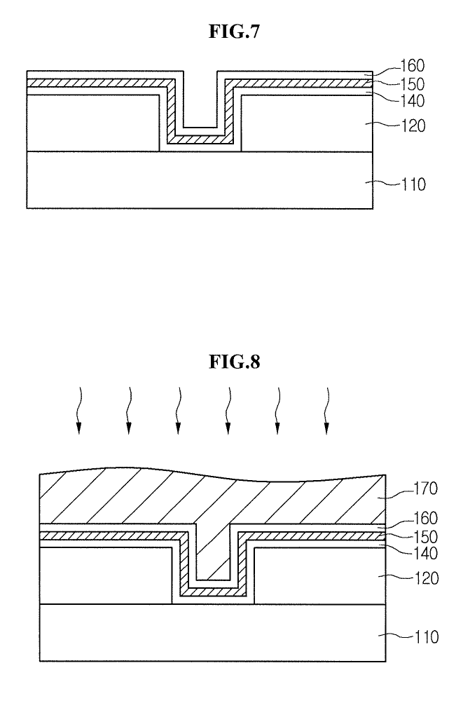

Accordingly, the reliability of the interlayer interconnection may be improved. FIGS. 7 to 13 are views for illustrating a method for forming a damascene interconnection of a semiconductor device according to another embodiment of the present invention.

Referring to FIG. 7, a first interlayer dielectric layer 120 can be formed with a via hole pattern on a semiconductor substrate 110 including a thin film having a device electrode or a conductive layer. Then, a first diffusion barrier 140, a first seed layer 150 and a first metal layer 160 can be sequentially formed on the first interlayer dielectric layer 120.

Here, the first seed layer 150 can be formed by depositing copper, and the first metal layer 160 may include aluminum, manganese, magnesium, silver, gold, or silicon as described above.

Then, referring to FIG. 8, copper 170 can be filled in the via hole pattern for forming a first copper interconnection.

Then, a heat treatment process can be performed on the resulting substrate in a temperature range of 300° C. ±100° C.

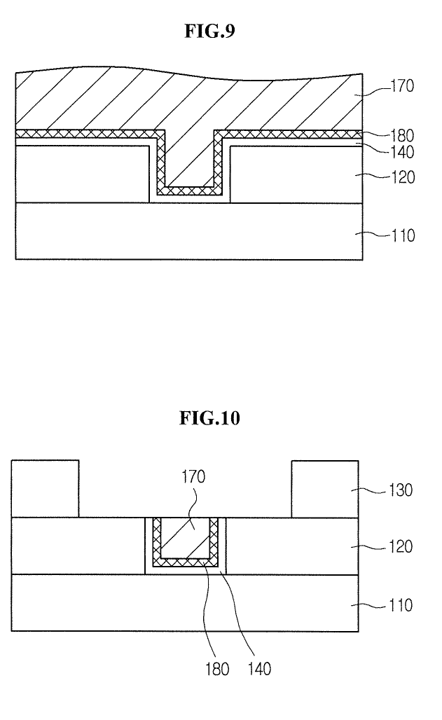

Referring to FIG. 9, the first metal layer 160 reacts with copper around the first metal layer 160 because of the heat treatment process, so as to form a first alloy layer 180 in the form of CuₓY_{z}.

The first alloy layer 180 helps prevent scratch from occurring in the CMP process together with a second alloy layer described below.

During the heat treatment process, the first seed layer 150 can be diffused into the first copper interconnection 170 while promoting the growth of copper to be filled in the via hole pattern. Accordingly, the first alloy layer 180 is formed on the first diffusion barrier 140.

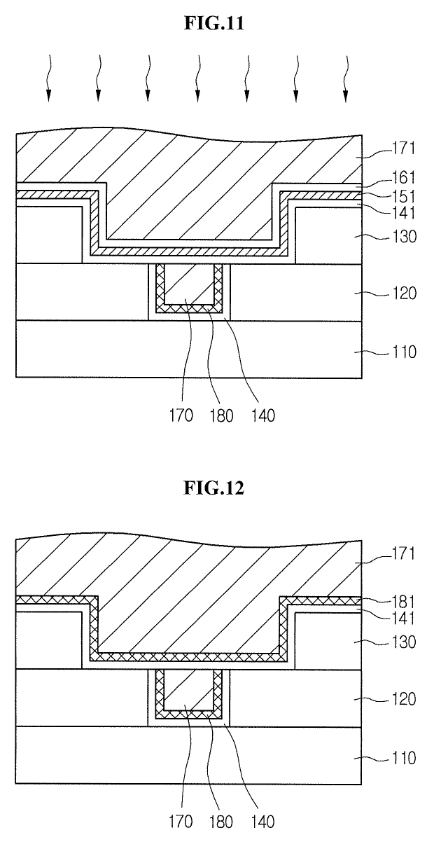

Next, referring to FIG. 10, a planarization process of the first copper interconnection 170 can be performed by the CMP process.

Then, a second interlayer dielectric layer 130 having a trench pattern can be formed on the first interlayer dielectric layer 120. The method for forming the second interlayer dielectric layer 130 having the trench pattern may include a normal etching process, so the detailed description thereof will be omitted.

Referring to FIG. 11, a second diffusion barrier 141, a second seed layer 151 and a second metal layer 161 can be sequentially stacked on the second interlayer dielectric layer 130 having the trench pattern.

Then, copper 171 can be formed on the second metal layer 161, so as to form a second copper interconnection. Then, the heat treatment process can be performed at the same temperature condition as the previous process explained above, so that the second metal layer 161 may react with copper around the second metal layer 161.

Accordingly, referring to FIG. 12, the second metal layer 161 reacts with copper through the heat treatment process, so that the second metal layer 161 becomes a second alloy layer 181 that serves to minimize or prevent scratch in the following CMP process.

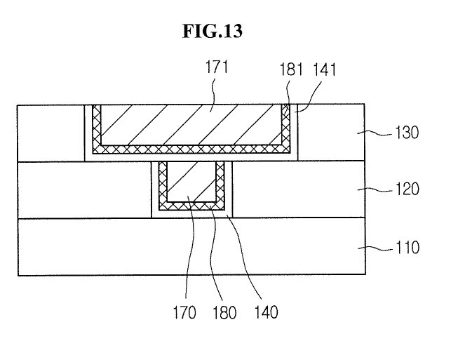

Referring to FIG. 13, a planarization process can be performed relative to a surface of the second copper interconnection 171 through the CMP process.

In particular, because the first and second alloy layers 180 and 181 are formed under the first and second copper interconnections 170 and 171, respectively, the hardness of the first and second copper interconnections 170 and 171 increase, thereby preventing scratch from being formed on the first and second copper interconnections 170 and 171 in the CMP process.

The method for manufacturing the damascene interconnection of the semiconductor device and the damascene interconnection manufactured by the same have advantages, such as an increase of hardness of the copper interconnection and an effectiveness of the CMP process.

In addition, since the alloy layer is formed under the copper interconnection, a grain size of the copper interconnection can be controlled.

Accordingly, as the semiconductor device is highly integrated, the reliability of the semiconductor device and interconnection between layers can be improved.

It should be understood that the examples and embodiments described herein are for illustrative purposes only and that various modifications or changes in light thereof will be suggested to persons skilled in the art and are to be included within the spirit and purview of this application.

I claim:

1. A method for manufacturing an interconnection of a semiconductor device, comprising:
forming an interlayer dielectric layer on a semiconductor substrate;
forming a damascene pattern on the interlayer dielectric layer;
depositing a seed layer on the interlayer dielectric layer;
depositing a metal layer on the seed layer;
depositing copper on the metal layer for forming a copper interconnection; and
performing a heat treatment process such that the metal layer reacts with the copper to produce an alloy layer including copper.

2. The method of claim 1, further comprising depositing a diffusion barrier layer on the interlayer dielectric layer prior to depositing the seed layer.

3. The method of claim 1, wherein the metal layer comprises aluminum, manganese, magnesium, silver, or gold.

4. The method of claim 1, wherein the metal layer comprises aluminum, and is formed to a thickness of 300 Å or less.

5. The method of claim 1, wherein the heat treatment is performed at a temperature range of 300° C. ±100° C.

6. The method of claim 1, further comprising performing a CMP process after the heat treatment process to form the copper interconnection, wherein the alloy layer improves an efficiency of the CMP process.

7. A method for manufacturing a damascene interconnection of a semiconductor device, comprising:
depositing a predetermined metal by PVD or CVD to form a metal layer on a damascene pattern;
forming a copper layer on the metal layer for forming a copper interconnection; and
performing a heat treatment process such that the metal layer reacts with the copper layer to produce an alloy layer including copper.

8. The method of claim 7, wherein the metal layer comprises aluminum (Al), manganese (Mn), magnesium (Mg), silver (Ag), or gold (Au), and is formed to a thickness of 300 Å or less.

9. The method of claim 7, wherein the heat treatment process is performed at a temperature range of 300° C. ±100° C.

10. An interconnection of a semiconductor device, comprising:
an interlayer dielectric layer having a damascene pattern formed on a semiconductor substrate;
an alloy layer formed in the damascene pattern by a predetermined heat treatment process, wherein the alloy includes copper; and
a copper interconnection formed on the alloy layer.

11. The interconnection of the semiconductor device of claim 10, wherein the alloy including copper formed by the predetermined heat treatment process is formed by the reaction between the copper layer and one selected from the group consisting of aluminum (Al), manganese (Mn), magnesium (Mg), silver (Ag), and gold (Au).

12. The interconnection of the semiconductor device of claim 10, wherein the alloy layer comprises AlCu.

13. The interconnection of the semiconductor device of claim 10, further comprising a diffusion barrier formed on the interlayer dielectric layer.
